(19) United States
(12) Patent Application Publication
(10) Pub. No.: US 2017/0084818 A1
(43) Pub. Date: Mar. 23, 2017

(54) SELF-RECOVERY MAGNETIC RANDOM ACCESS MEMORY UNIT

(71) Applicant: HGST Netherlands B.V., Amsterdam (NL)

(72) Inventors: Patrick M. BRAGANCA, San Jose, CA (US); Luis CARGNINI, San Jose, CA (US); Jordan A. KATINE, Mountain View, CA (US); Hsin-Wei TSENG, Cupertino, CA (US)

(73) Assignee: HGST Netherlands B.V., Amsterdam (NL)

(21) Appl. No.: 14/859,002

(22) Filed: Sep. 18, 2015

(51) Int. Cl. H01L 43/02; H01L 45/00

(52) U.S. Cl. CPC H01L 43/02; H01L 45/12

(57) ABSTRACT

The present disclosure generally relates to spin-torque-transfer magnetoresistive random access memory (STT-MRAM) memory cells. In the magnetic tunnel junction (MTJ) of the STT-MRAM memory cell, a 1 nm thick barrier layer having a triclinic crystalline structure is doped with B, N, or C. By applying a positive voltage to the MTJ, the magnetic state of the free layer of the MTJ may be switched. By increasing the voltage applied to the MTJ, the MTJ may change to operate as a ReRAM memory cell, and the crystalline structure of the barrier layer may switch to monoclinic. Before reaching the breakdown voltage, a negative voltage may be applied to the MTJ to switch the crystalline structure of the barrier layer back to triclinic. Once the negative voltage is applied and the crystalline structure of the barrier layer is changed back to triclinic, the MTJ may function as a STT-MRAM cell once again.

### BACKGROUND OF THE DISCLOSURE

Field of the Disclosure

Embodiments of the present disclosure generally relate to a non-volatile memory, particularly spin-torque-transfer magnetoresistive random access memory (STT-MRAM).

Description of the Related Art

The heart of a computer is a magnetic recording device which typically includes a rotating magnetic media or a solid state media device. A number of different memory technologies exist today for storing information for use in a computing system. These different memory technologies may, in general, be split into two major categories: volatile memory and non-volatile memory. Volatile memory may generally refer to types of computer memory that requires power to retain stored data. Non-volatile memory, on the other hand, may generally refer to types of computer memory that do not require power in order to retain stored data.

Recently, a number of emerging technologies have drawn increasing attention as potential contenders for next generation non-volatile memory. One such memory technology is magnetoresistive random access memory (MRAM). MRAM offers fast access time, infinite read/write endurance, radiation hardness, and high storage density. Unlike conventional RAM chip technologies, MRAM data is not stored as an electric charge, but instead stores data bits using magnetic charges. MRAM devices may contain memory elements formed from two magnetically polarized plates, each of which can maintain a magnetic polarization field, separated by a thin insulating layer, which together form a magnetic tunnel junction (MTJ) layer. The thin insulating layer may be a barrier layer. MTJ memory elements can be designed for in-plane or perpendicular magnetization of the MTJ layer structure with respect to the firm surface. One of the two plates is a permanent magnet (i.e., has a fixed magnetization) set to a particular polarity; the polarization of the other plate will change (i.e., has free magnetization) to match that of a sufficiently strong external field. Therefore, the cells have two stable states that allow the cells to serve as non-volatile memory cells.

One type of MRAM employing the MTJ memory element is spin-torque-transfer MRAM (STT-MRAM). However, the MTJ memory elements in STT-MRAM devices suffer from wear-effects due to driving a sufficient amount of current for switching through the MTJ, including through the barrier layer. Typically, a large amount of write current is required for switching the state of the cell. Over time, the barrier layer breaks down due to the amount of current, rendering the MTJ inoperable.

Therefore, there is a need in the art for an improved MRAM device that is capable of recovering and operating if too much current is driven through the barrier layer of the MTJ.

### SUMMARY OF THE DISCLOSURE

The present disclosure generally relates to STT-MRAM memory cells. In the MTJ of the STT-MRAM memory cell, a 1 nm thick barrier layer having a triclinic crystalline structure is doped with B, N, or C. By applying a positive voltage to the MTJ, the magnetic state of the free layer of the MTJ may be switched. By increasing the voltage applied to the MTJ, the MTJ may change to operate as a ReRAM memory cell, and the crystalline structure of the barrier layer may switch to monoclinic. Before reaching the breakdown voltage, a negative voltage may be applied to the MTJ to switch the crystalline structure of the barrier layer back to triclinic. Once the negative voltage is applied and the crystalline structure of the barrier layer is changed back to triclinic, the MTJ may function as a STT-MRAM cell once again.

In one embodiment, a memory cell comprises a substrate, a fixed layer disposed over the substrate, and a barrier layer disposed on the fixed layer. The barrier layer is doped with boron, nitrogen, or carbon, and the barrier layer is less than ten nanometers thick. A free layer is disposed on the barrier layer.

In another embodiment, a storage device comprises a bottom contact, a top contact disposed adjacent to the bottom contact, and a memory cell disposed adjacent to the top contact. The memory cell further comprises a substrate, a fixed layer disposed over the substrate, and a barrier layer disposed on the fixed layer. The barrier layer is doped with boron, nitrogen, or carbon, and the barrier layer is less than ten nanometers thick. A free layer is disposed on the barrier layer.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a STT-MRAM memory cell, according to one embodiment.

FIG. 2 illustrates the amount of voltage applied to the MTJ versus the state of the MTJ.

FIG. 3 illustrates a flow chart of the changing MTJ states.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following, reference is made to embodiments of the disclosure. However, it should be understood that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in a claim(s).

The present disclosure generally relates to STT-MRAM memory cells. In the MTJ of the STT-MRAM memory cell, a 1 nm thick barrier layer having a triclinic crystalline structure is doped with B, N, or C. By applying a positive voltage to the MTJ, the magnetic state of the free layer of the MTJ may be switched. By increasing the voltage applied to the MTJ, the MTJ may change to operate as a ReRAM memory cell, and the crystalline structure of the barrier layer may switch to monoclinic. Before reaching the breakdown voltage, a negative voltage may be applied to the MTJ to switch the crystalline structure of the barrier layer back to triclinic. Once the negative voltage is applied and the crystalline structure of the barrier layer is changed back to triclinic, the MTJ may function as a STT-MRAM cell once again.

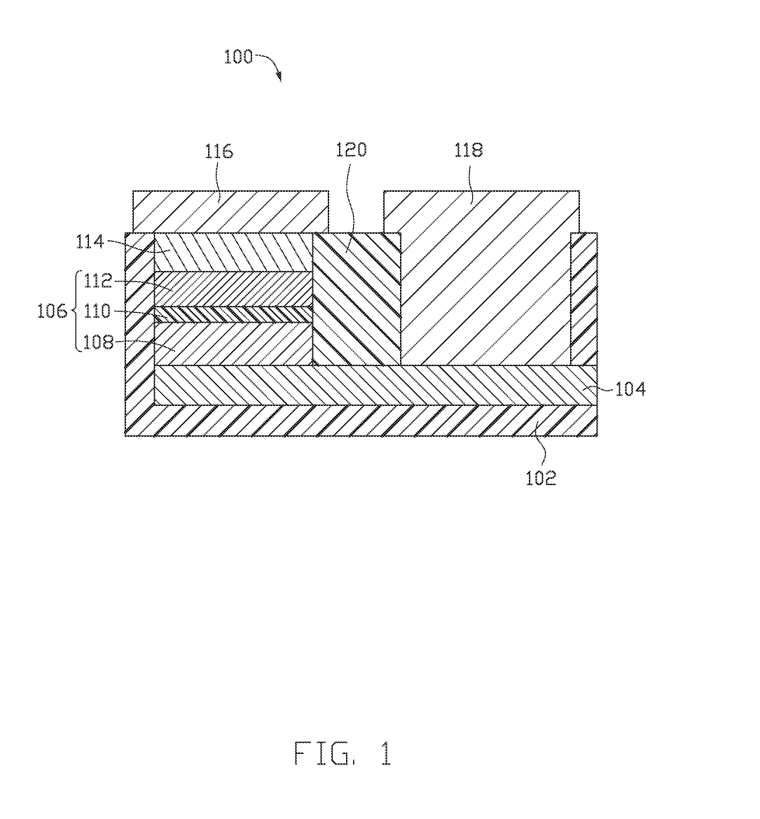

FIG. 1 is a STT-MRAM memory cell 100, according to one embodiment. The memory cell 100 comprises a substrate 102 and a first gate electrode 104 disposed on the substrate 102. A magnetic tunnel junction element (MTJ) 106, or a data bit, is disposed on a portion of the first gate electrode 104. The MTJ or bit 106 may be in a state representing either a “1” or a “0” in binary. The MTJ 106 is comprised of a fixed layer 108 having a fixed magnetization, a barrier layer 110, and a free layer 112 having a free magnetization. A second gate electrode 114 is disposed above the free layer 112. A top contact 116 may be disposed on the second gate electrode 114. A bottom contact 118 may be disposed adjacent the top contact 116 and the MTJ 106. The bottom contact 118 may be in contact with a portion of the first gate electrode 104. The bottom contact 118 may be spaced from the MTJ 106 by an insulating layer 120. The insulating layer 120 may be in contact with a portion of the first gate electrode 104 and the MTJ 106.

A pinning layer (not shown) may be disposed between the first gate electrode 104 and the fixed layer 108. The pinning layer may determine the magnetization of the fixed layer 108. In one embodiment, the fixed layer 108 is disposed between the barrier layer 110 and the second gate electrode 114, and the free layer 112 is disposed between the barrier layer 110 and the first gate electrode 104. In such an embodiment, a pinning layer would be disposed between the second gate electrode 114 and the fixed layer 108.

The substrate 102 may be comprised of SiO₂, and may have a thickness of about 385 μm. The first gate electrode 104 and the second gate electrode 114 may be comprised of Ta and/or Ru, or IrMn. The first gate electrode 104 and the second gate electrode 114 may have a thickness of about 100 nm. The fixed layer 108 and the free layer 112 may be comprised of CoFe or CoFeB, and may have a thickness of about 0.3 nm to 3 nm. The top contact 116 and the bottom contact 118 may be comprised of Cr/Au, Cu, Al, W, or Pt. The top contact 116 may have a thickness of about 10 nm to 50 nm, and the bottom contact may have a thickness of about 100 nm or more. The insulating layer 120 may comprise an oxide, such as AlOₓ, and may have a thickness about equivalent to the height of the STT-MRAM device, which may be about 100 nm of SiOₓ, AlOₓ, SiN, or spin-on-glass.

The barrier layer 110 may be comprised of an oxide, such as MgO, and the barrier layer 110 may be doped with boron, carbon, or nitrogen. In one embodiment, the barrier layer 110 is less than 10 nm thick. In another embodiment, the barrier layer 110 is less than 5 nm thick. In yet another embodiment, the barrier layer 110 is about 1 nm thick. If the fixed layer 108 and the free layer 112 comprise boron, the B atoms may migrate to the barrier layer 110. The doped barrier layer 110 provides resistive switching to the MTJ 106, helping to prevent a hard-breakdown of the barrier layer 110 due to large amounts of current.

Reading the polarization state of the STT-MRAM cell 100 is accomplished by measuring the electrical resistance of the STT-MRAM cell's 100 MTJ 106. A particular cell is conventionally selected by powering an associated transistor that switches current from a supply line through the MTJ 106 to a ground. Due to the tunneling magnetoresistance effect, the electrical resistance of the STT-MRAM cell 100 may change due to the relative orientation of the polarizations in the free layer 112 and the fixed layer 108 of the MTJ 106. By measuring the resulting current, the resistance inside any particular STT-MRAM cell 100 may be determined, and from this the polarity of the free (writable) layer 112 determined. If the free layer 112 and the fixed layer 108 of the MTJ 106 have the same polarization, the state is considered to mean state “0,” and the resistance is “low.” However, if the free layer 112 and the fixed layer 108 are of opposite polarization, the resistance may be higher than that of state “0” which correlates to state “1”.

The fixed layer 108 may provide a reference frame required for reading and writing. The STT effect may enable the magnetic state of free layer 112 to be changed if the torque is sufficiently strong, thus permitting the writing of information. Within the MTJ 106 resistance may be low when the magnetization of the fixed layer 108 and free layer 112 are aligned in the same direction and are parallel. However, resistance may be high when the magnetization of the fixed layer 108 and the free layer 112 are aligned in opposite directions and are anti-parallel.

If too much positive voltage is applied to the MTJ 106 during the lifetime of the MTJ 106, the barrier layer 100 breaks down, rendering the MTJ 106 inoperable. However, a resistive switching phenomenon may be observed in the MTJ 106 between the write state and the breakdown state. In the resistive switching state, the MTJ 106 may employ reversible switching between the high resistance state and the low resistance state due to electric stress. Additionally, the MTJ 106 functions as a resistive random access memory (ReRAM) rather than as a STT-MRAM in the resistive switching state. The MTJ 106 functions in the resistive switching state when too much positive voltage is applied to the MTJ 106 to function in the STT-MRAM write state, but not enough positive voltage has been applied to break down the barrier layer 110 of the MTJ 106, or to reach the breakdown voltage.

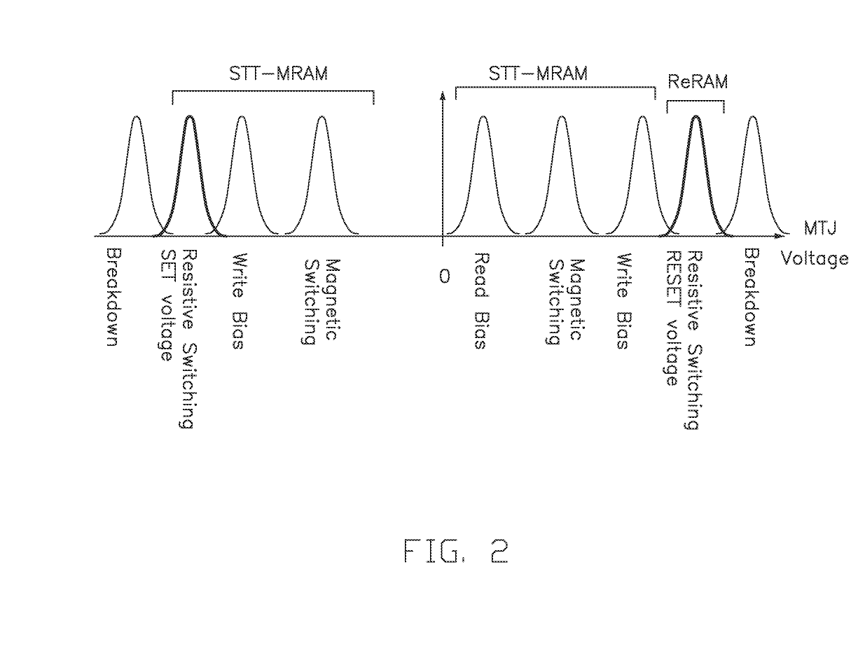

FIG. 2 illustrates the amount of voltage applied to the MTJ 106 of memory cell 100 versus the state of the MTJ 106 of memory cell 100. As shown in FIG. 2, a small amount of positive voltage is required to perform the read operation of the MTJ 106. A slightly increased amount of positive voltage is required to switch the magnetization state of the free layer 112. During the read bias state, the magnetic switching state, and the write bias state, the MTJ 106 operates as STT-MRAM. However, if an abundance of positive voltage is applied, the MTJ 106 may operation in a resistive switching mode, as shown in FIG. 2. During the resistive switching mode, the MTJ 106 operates as a ReRAM. By increasing the amount of applied positive voltage, the barrier layer 110 breaks down, rendering the MTJ 106 inoperable. It is widely believed that once a MTJ 106 functions in the resistive switching mode, the MTJ 106 becomes inoperable. However, utilizing B, C, or N in the MgO barrier layer 110, allows the MTJ 106 to once again function as a STT-MRAM after being in the resistive switching mode.

While the MTJ 106 is in the STT-MRAM mode, the B, C, or N doped barrier layer 110 has a triclinic (or monoclinic) crystalline structure. By applying additional voltage to MTJ 106 to switch to the ReRAM mode, the crystalline structure of the barrier layer 110 changes to monoclinic (or triclinic). The crystalline structure of the barrier layer 110 is changed when enough positive voltage is applied to the MTJ 106 to change the state of the MTJ 106 to the resistive switching reset voltage in FIG. 2. Thus, the crystalline structure of the barrier layer 110 changes due to the high amount of voltage applied and the high resistance state. To change the crystalline structure from monoclinic back to triclinic, and thus, to go from functioning as a ReRAM back to STT-MRAM, a lower resistance state is needed. To lower the resistance state, a negative voltage may be applied to the MTJ 106. The amount of negative voltage applied may be the same as the amount of positive voltage that was applied in order to reach the resistive switching state. The amount of negative voltage applied may vary from the amount of positive voltage applied by ±10-20%. The B, C, or N doping of the MgO barrier layer 110 allows the crystalline structure to switch back and forth more readily. Thus, the negative voltage applied may change the state of the MTJ 106 to the resistive switching set voltage state shown in FIG. 2.

By applying negative voltage to the MTJ 106 when the MTJ 106 is functioning in the resistive switching state, the crystalline structure of the barrier layer 110 is changed back to triclinic. The negative voltage applied may be increased in small increments until the resistance is lowered and the memory cell 100 is functioning as a STT-MRAM once again. Once the crystalline structure of the barrier layer 110 has been changed back to triclinic, a positive voltage may then be applied again to either read or write the MTJ 106 in STT-MRAM mode. The state of the MTJ 106 may be monitored to determine whether the STT-MRAM state has been achieved. Thus, the MTJ 106 may self-recover, enhancing the capability of error-correction due to physical repairing of the MTJ 106.

Doping the MgO barrier layer 110 with B, N, or C permits the barrier layer 110 to display high magnetoresistance (MR) recovery properties. The high MR recovery of the doped barrier layer 110 allows the MTJ 106 to go from functioning as a ReRAM back to functioning as a STT-MRAM. The B, C, or N doped MgO barrier layer 110 may become more uniform in structure, and have a lower surface roughness or RA value. Additionally, the doped barrier layer 110 has a similar crystal lattice as an un-doped MgO layer may have. The B, C, or N doped MgO barrier layer 110 may have a smaller band gap and tunneling barrier than an un-doped MgO layer may have.

By implementing the hard-error correction scheme to improve ECC in the MTJ 106, the lifetime of the MTJ 106 may be increased. Moreover, since the MTJ 106 is able to function as a STT-MRAM after functioning as a ReRAM, the MTJ 106 experience advantages from both STT-MRAM and ReRAM devices. For example, STT-MRAM devices are high-density, high-speed, and low power. In one embodiment, the memory cell 100 switches the state of the free layer 112 in less than 10 ns. ReRAM devices are able to function at high resistances. Additionally, since the barrier layer 110 may have a thickness of only 1 nm, space within the memory cell may be conserved, allowing the overall memory cell to be smaller.

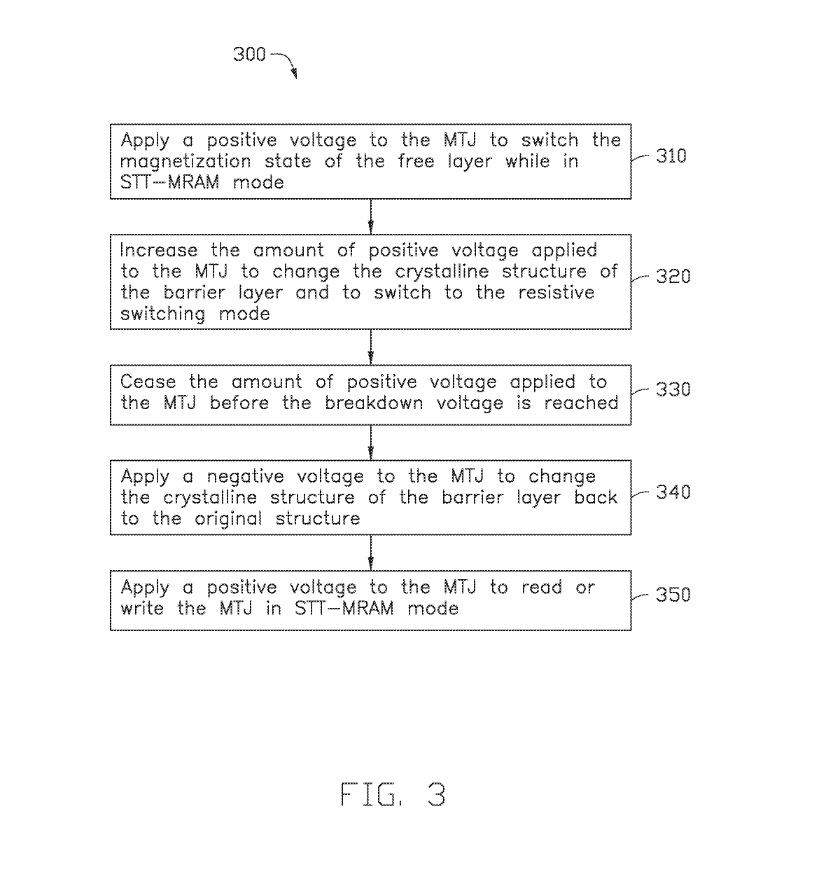

FIG. 3 illustrates a flow chart 300 describing how the MTJ changes states. At operation 310, a positive voltage is applied to the MTJ to switch the magnetization state of the free layer of the MTJ while operating in STT-MRAM mode. During operation 310, the B, C, or N doped barrier layer of the MTJ may have a triclinic crystalline structure. At operation 320, the amount of positive voltage applied to the MTJ is increased to change the crystalline structure of the B, C, or N doped barrier layer and to switch to the resistive switching mode. At operation 320, the MTJ may be functioning as a ReRAM, rather than a STT-MRAM. The crystalline structure of the B, C, or N doped barrier layer may be switched to monoclinic during operation 320. The memory cell may also function at a higher resistance state. At operation 330, the amount of positive voltage applied to the MTJ is ceased before the breakdown voltage is reached. If the breakdown voltage is reached, the MTJ may be unable to self-recover.

At operation 340, a negative voltage is applied to the MTJ to change the crystalline structure of the B, C, or N doped barrier layer back to the original crystalline structure. The crystalline structure of the B, C, or N doped barrier layer may be switched to triclinic. By applying the negative voltage, the resistance state is lowered, allowing the MTJ to function as a STT-MRAM. The amount of negative voltage applied may be the same as the amount of positive voltage that was applied in order to reach the resistive switching state. The amount of negative voltage applied may vary from the amount of positive voltage applied by ±10-20%.

At operation 350, a positive voltage is applied to the MTJ to read or write the MTJ in STT-MRAM mode. While the MTJ is functioning in STT-MRAM mode, the B, C, or N doped barrier layer may have the triclinic crystalline structure. Operations 310-350 may be repeated numerous times. Operations 310-350 may be unable to be repeated if the positive voltage breakdown or the negative voltage breakdown is reached.

In one embodiment, a negative voltage is applied to the MTJ to switch the magnetic state of the free layer. Operations 310-350 may still apply, however the negative and the positive voltages may be switched. If too much negative voltage is applied to the MTJ, the crystalline structure of the B, C, or N doped barrier layer may change to monoclinic. To switch the crystalline structure of the B, C, or N doped barrier layer back to triclinic, a positive voltage may be applied. Thus, too much negative voltage may also change the MTJ to function in the resistive switching mode. By applying a positive voltage, the STT-MRAM mode may be obtained once again.

Therefore, by doping the 1 nm thick MgO barrier layer with B, N, or C, the memory cell is able to self-recover back to the STT-MRAM mode from the resistive switching state. Doping the MgO barrier layer with B, N, or C permits the crystalline structure of the barrier layer to switch easily between the different crystalline structures. Thus, the MTJ of the memory cell may self-recover more readily, enhancing the capability of error-correction due to physical repairing of the MTJ. Additionally, the lifetime of the memory cell may be prolonged, as the memory cell is able to recover from the resistive switching state before the breakdown voltage is reached.

While the foregoing is directed to embodiments of the present disclosure, other and further embodiments of the disclosure may be devised without departing from the basic scope thereof, and the scope thereof is determined by the claims that follow.

1. A memory cell, comprising:
a substrate;
a first gate electrode disposed on the substrate;
a fixed layer disposed on the first gate electrode;
a barrier layer disposed on the fixed layer, wherein the barrier layer is doped with nitrogen, and wherein the barrier layer is less than ten nanometers thick;
a free layer disposed on the barrier layer; and
a second gate electrode disposed on the free layer.

2. The memory cell of claim 1, wherein the barrier layer comprises magnesium oxide.

3. The memory cell of claim 1, wherein the barrier layer is less than 5 nanometers thick.

4. The memory cell of claim 3, wherein the barrier layer is about 1 nanometer thick.

5-7. (canceled)

8. The memory cell of claim 1, wherein the free layer and the fixed layer comprise cobalt-iron-boron.

9. The memory cell of claim 1, wherein the barrier layer has a triclinic crystalline structure.

10. The memory cell of claim 1, wherein the barrier layer has a monoclinic crystalline structure.

11. A storage device comprising:
a bottom contact;
a top contact disposed adjacent to the bottom contact;
a memory cell disposed adjacent to the top contact, wherein the memory cell further comprises:
a substrate;
a first gate electrode disposed on the substrate;
a fixed layer disposed on the first gate electrode;
a barrier layer disposed on the fixed layer, wherein the barrier layer is doped with nitrogen, and wherein the barrier layer is less than ten nanometers thick;
a free layer disposed on the barrier layer; and
a second gate electrode disposed on the free layer.

12. The memory cell of claim 11, wherein the barrier layer comprises magnesium oxide.

13. The memory cell of claim 11, wherein the barrier layer is less than 5 nanometers thick.

14. The memory cell of claim 13, wherein the barrier layer is about 1 nanometer thick.

15-17. (canceled)

18. The memory cell of claim 11, wherein the free layer and the fixed layer comprise cobalt-iron-boron.

19. The memory cell of claim 11, wherein the barrier layer has a triclinic crystalline structure.

20. The memory cell of claim 11, wherein the barrier layer has a monoclinic crystalline structure.
